(19) United States
(12) Patent Application Publication
(10) Pub. No.: US 2015/0367873 A1
(43) Pub. Date: Dec. 24, 2015

(54) METHOD AND DEVICE FOR WARNING PERSONS IN THE VICINITY OF AN HF FIELD-EMITTING DEVICE

(71) Applicant: SIEMENS AKTIENGESELLSCHAFT, München (DE)

(72) Inventors: HENDRIK IBENDORF, KLEINMACHNOW (DE); OLAF RICHTER, BERLIN (DE)

(73) Assignee: SIEMENS AKTIENGESELLSCHAFT, MUENCHEN (DE)

(21) Appl. No.: 14/766,502

(22) PCT Filed: Jan. 3, 2014
(86) PCT No.: PCT/EP2014/050042

§ 371 Date: Aug. 7, 2015

(30) Foreign Application Priority Data
Feb. 15, 2013 (DE) 10 2013 202 465.7

(51) Int. Cl. B61L 23/06; G08B 21/02; G01R 29/08

(52) U.S. Cl. CPC B61L 23/06; G01R 29/0878; G08B 21/02

(57) ABSTRACT

A method warns persons who are in the vicinity of an high-frequency (HF) field-emitting device, such as an European train control system (ETCS) antenna of a rail vehicle. In order to be able to reliably warn persons of the presence of radiation that is detrimental to health, the HF field is extracted by an antenna arrangement, the extracted signal actuating, by a power-measuring device, a signaling device for the optical and/or acoustic signaling of an ON/OFF state of the device, in particular the ETCS antenna.

The invention relates to a method for warning persons in the vicinity of an HF field-emitting device, especially an ETCS (European Train Control System) antenna of a rail vehicle, and also to a device related thereto.

Warning persons when they are in the vicinity an HF field-emitting device is necessary because of the radiation that is detrimental to health. Such devices are used in many areas, for example in industrial plants, communication systems and traffic systems. For maintenance, diagnostic or installation purposes in particular, direct contact between persons and these devices is inevitable. The description given below essentially relates to an ETCS antenna of a rail vehicle emitting an HF field, without the invention being intended to be restricted to this application.

ETCS antennas on rail vehicles are used for absolute global positioning between railroad and rail vehicle. Their transmit power with up to 10 Watts and the frequency range that they use, at around 27 MHz, are detrimental to health for persons in the immediate vicinity of an active, i.e. switched-on, ETCS antenna. With track which is level with the ground it is not possible for persons to be endangered since the ETCS antenna is disposed in the underfloor area of the rail vehicle and thus direct contact between a person and the ETCS antenna is not normally possible. For maintenance work on the other hand the rail vehicle is parked on raised tracks, for example in a depot or in an operator's workshop. In such cases it must be insured that the ETCS antenna is switched off for personal protection or that a sufficiently large safety distance is maintained.

A simple control light on the ETCS antenna, in order to display its on or off state, is not permitted since a possible failure of the control light which cannot be revealed would signal a false safety.

Currently safety when working on the ETCS antenna is only covered by operational regulations and working instructions. Trained personnel, before working inside the vehicle, must make sure that the ETCS antennas are switched off. The danger from HF radiation is not evident for insufficiently trained personnel.

Usually warning notices are attached in the depot area for raised tracks, which warn in general terms about the dangers of high-frequency electromagnetic fields which are emitted by the ETCS antenna. These measures, especially in the absence of specialized knowledge of the maintenance personnel, are only insufficiently safe since the presence of an HF field is not obvious and therefore an absence of hazardous radiation could be suggested.

The underlying object of the invention is to specify a method and a device of a generic type, which clearly and unequivocally signal the on and off state of the device creating an HF field.

As far as the method is concerned the object is achieved by the HF field being extracted by means of antenna arrangement, wherein the extracted signal controls a signaling device via a power metering device for optical and/or acoustic signaling of an on/off state of the device.

The object is also achieved by a device having an HF detector with an antenna arrangement and a power meter and which is connected to a signaling device for optical and/or acoustic signaling of an on/off state of the device, especially of an ETCS antenna of a rail vehicle.

In this way the presence of an HF field detrimental to health is emphatically signaled. The HF detector makes it possible, with an ETCS antenna of a rail vehicle, to extract the 27 MHz signal and to pre-amplify it, filter it and measure its power. In the simplest case the power can be measured via rectifiers with a comparator circuit or an active demodulator for evaluation. The output signal of the HF detector generates a warning tone if the ETCS antenna is switched on and/or for example a red and/or flashing warning light. The warning light function can also be used to make a display tablet visible, which indicates that before work is begun in the underfloor area of the rail vehicle it is vital that the currently active ETCS antennas be switched off.

Acoustic and/or optical signaling also covers any other signaling option in terms of the invention. It only has to be guaranteed that persons in danger from radiation are given sufficient warning.

In accordance with claim 3 there is provision for the antenna arrangement to have a leaky feeder cable resting on the rail feet of both rails of a raised track. In the area in which the rail vehicle is standing a leaky feeder cable is laid along the track in the left and in the right rail foot. Together with the respective rail this forms the antenna arrangement for receiving the HF field, namely the 27 MHz signal of the ETCS antenna. After pre-amplification and filtering of said signal the power can be measured and used for controlling the signaling device. A stationary device of this type is especially suitable for depots and operator's workshops with raised tracks.

Since a number of tracks located close to one another are typically located in operator's workshops and depots there is the risk of crosstalk and thus of false detection. With an active ETCS antenna in the track section the measured power of both rails is the equal in size. In neighboring tracks on the other hand, because of the increasing distance from the ETCS antenna emitting the HF field, a smaller and quadratically falling power in relation to the two rails is measured. To evaluate this power curve and safely avoid crosstalk, there is provision in accordance with claim 4 for the leaky feeder cables of neighboring tracks to be connected to a common operations control center. In this way an assignment of the active ETCS antennas to the rail vehicle is readily possible. The connection between the individual leaky feeder cables and the operations control center can be made via Ethernet for example. The operations control center can directly control the danger signaling in the depot area in which the active ETCS antennas are located.

Instead of the leaky feeder cable as antenna arrangement, in accordance with claim 5 at least one frame or loop antenna laid in the longitudinal direction of the track with an HF resonance circuit is provided. Frame or loop antennas are especially suitable as receive antennas of the radiation to be measured for tracks at ground level or close to the ground. Depending on the circumstances in the hall of the depot or of the operator's workshop, especially relative to the track height and the track spacings, the loops or frames of the antenna arrangement are laid with an extent of appr. 5 m to appr. 50 m. To increase the selectivity the extent must be all the smaller the more disturbances from neighboring tracks are to be reckoned with. In this way it is possible to distinguish between the tracks on the basis of their receive level. The frame or loop antennas can be laid directly on the track foot. The signal injected into these receive antennas is transmitted via a transformer and a resonance circuit matched to 27 MHz to the power meter. The power is measured in the simplest case via rectifiers and comparator circuit for the purposes of creating an output signal suitable for controlling the respective signaling device.

Instead of a stationary HF detector with leaky feeder cable or frame or loop antennas as an antenna arrangement laid fixed to the track, which is preferably suitable for depots or operator's workshops, a mobile deployment of an HF detector can also be necessary. For this purpose there is provision in accordance with claim 6 for the HF detector to be embodied so as to the able to be carried with them by a person, wherein the antenna arrangement has a 3D antenna with HF resonant circuit. The portable device also contains the signaling device which generates a warning signal in the event of hazardous field strength.

The 3D antenna can be embodied for example by means of three individual coils or individual frame antennas disposed orthogonally in relation to one another, independent of the spatial orientation of the portable HF decoder. The power measurement is thus largely independent of the alignment of the receive antenna in relation to the ETCS antenna emitting the electromagnetic HF field.

In accordance with claim 7 a HF signal injection device for function testing of the HF detector is provided. In this way a failure of the warning function can also be established and passed onto the operations control center for example, so that an appropriate repair can be initiated. The HF signal injection device can be embodied for example such that a test signal or fault signal is emitted cyclically via a transmitter at 27 MHz in order to quasi simulate an active ETCS antenna. With a permanently installed HF detector with leaky feeder cable the test signal can be emitted for example via a transmitter integrated into the power meter at specific intervals and can be received by the antenna arrangement which is connected to the second leaky feeder cable of the second rail of the track.

In this way a function check is possible without the presence of a rail vehicle with ETCS antennas.

With portable HF decoders too a failure of the decoder can be revealed in a simple manner in that, in the case of the cyclically created fault signal, in each case specific warning lights or acoustic warning signals are created to indicate the operational or defective state. In order to guarantee the highest level of safety in the failure disclosure, the error display is equipped with signaling means able to be distinguished especially clearly from one another, for example red or green flashing, short staccato tone or a continuous warning tone. Errors beyond this are disclosed by the absence of one of these signals.

The invention is explained in greater detail below on the basis of figures, in which:

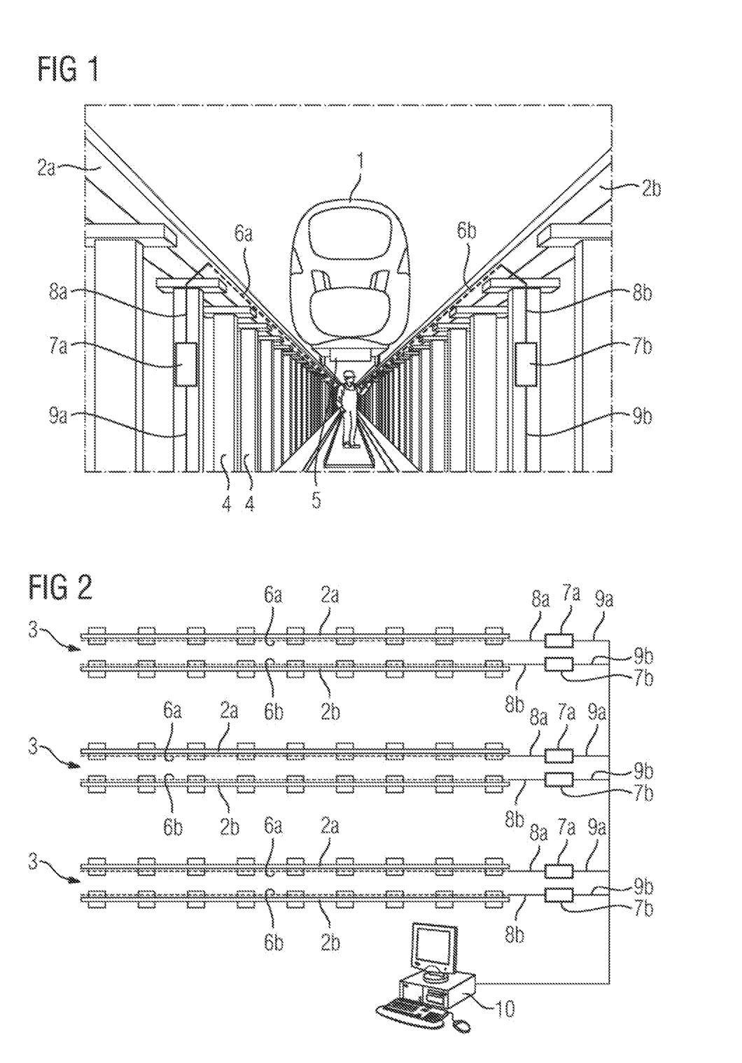

FIG. 1 shows a first form of embodiment of a detector device in an operator's workshop,

FIG. 2 shows the detector device according to FIG. 1 as a basic diagram,

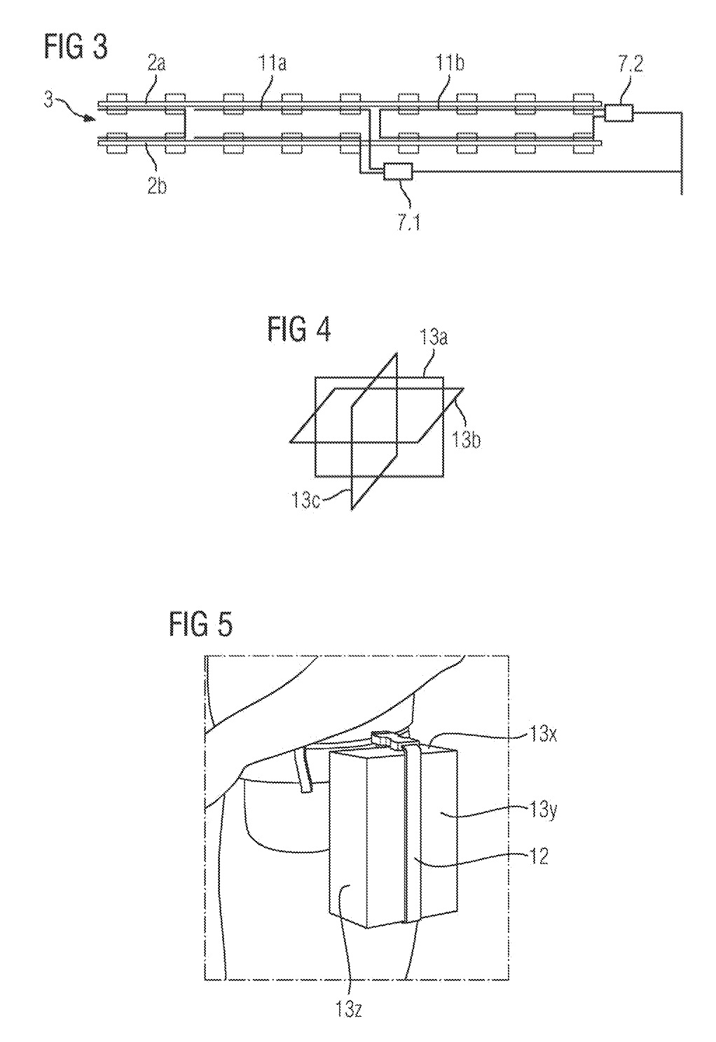

FIG. 3 shows a second form of embodiment of the detector device,

FIG. 4 shows a 3D antenna for a third portable form of embodiment of a detector device and

FIG. 5 shows a portable detector device with a further form of embodiment of the 3D antenna.

FIG. 1 illustrates an operator's workshop area in which a rail vehicle 1 is parked. To make the underfloor area of the rail vehicle 1 accessible, the two rails 2a and 2b of the track 3 are raised by means of rail stands 4. The rail vehicle 1 is equipped in its underfloor area, meaning its underside, with an ETCS antenna 5. In the active state, in which the ETCS antenna 5 is switched on, said antenna emits an HF field. The transmit power of around 10 W and the frequency range of 27 MHz usually used for ETCS antennas 5 are detrimental to health in the near field. For this reason an inventive warning device is provided for persons which, in a first form of embodiment, consists essentially of leaky feeder cables 6a and 6b, which rest on the rails 2a and 2b of the track 3, assigned evaluation devices 7a and 7b and also a signaling device not shown in the diagram for optical and/or acoustic signaling of the on/off state of the ETCS antenna 5. The leaky feeder cables 6a and 6b, together with the rails 2a and 2b, form receive antennas, which extract the HF field emitted by the ETCS antenna 5 in the on state and transmitted via connecting lines 8a and 8b to the evaluation device 7a or 7b respectively. For power supply and for forwarding the output signals the evaluation devices 7a and 7b are linked via Ethernet 9a and 9b to an operations control center 10 shown in FIG. 2.

FIG. 2 also shows a parallel connection of neighboring tracks 3 to avoid false alarms through crosstalk of the HF field of a switched-on ETCS antenna 5 to usually closely-adjacent tracks 3 in operator's workshops and depots. The power levels received in the common operations control center 10 in relation to the rails 2a and 2b of the tracks 3 are evaluated such that an assignment of the warning signaling to the track 3 on which the rail vehicle 1 with the emitting ETCS antenna 5 is parked can be undertaken. In such cases use is made of the fact that the radiation intensity decreases quadratically with a distance from the radiation source.

FIG. 3 shows a further variant for the embodiment of receive antennas close to the rail. Instead of leaky feeder cables 6a and 6b, loop antennas 11a and 11b are provided, which are especially suitable for tracks 3 level with the ground or close to the ground. In this case each loop antenna 11a, 11b is connected to an evaluation device 7.1, 7.2. The extent of the loop antenna 11a, 11b amounts to between 5 m and 50 m in the track direction, wherein this longitudinal extent must be small to increase the selectivity in relation to disturbances from neighboring tracks.

For a wearable form of embodiment of the warning device a portable 3D antenna is provided as the receive antenna, which is housed in a carrying case 12, FIG. 5, together with the evaluation device and the signaling device. The 3D antenna in this case can consist of three individual antennas 13a, 13b and 13c nested orthogonally in relation to one another, as shown in FIG. 4, or also individual antennas 13x, 13y and 13z in a box shape disposed orthogonally in relation to one another, which are to be accommodated practically in or on the box-shaped carrying case 12 in accordance with FIG. 5.

1-7. (canceled)

8. A method for warning persons in a vicinity of a device emitting a high-frequency field, which comprises the steps of:
extracting the HF field by means of an antenna configuration, an extracted signal, via a power meter device, activating a signaling device for optical and/or acoustic signaling of an on/off state of the device emitting the HF field.

9. The method according to claim 8, which further comprises extracting the HF field from an European train control system antenna of a rail vehicle.

10. A device, comprising:
a signaling device; and
an HF detector having an antenna configuration and a power meter connected to said signaling device for optical and/or acoustic signaling of an on/off state of an apparatus emitting a high-frequency field, said HF detector extracting the HF field by means of said antenna configuration, and an extracted signal, via said power meter, activating said signaling device for the optical and/or acoustic signaling of the on/off state of the apparatus emitting the HF field.

11. The device according to claim 10, wherein said antenna configuration has a leaky feeder cable resting against a rail feet of both rails of a raised track.

12. The device according to claim 11, further comprising an operations control center, said leaky feeder cables of neighboring tracks are connected to said operations control center.

13. The device according to claim 10, wherein said antenna configuration has at least one frame antenna or loop antenna with a HF resonant circuit laid in a longitudinal direction of a rail track.

14. The device according to claim 10, wherein said HF detector is embodied to be carried by a person, said antenna configuration has a 3D antenna with HF resonant circuit.

15. The device according to claim 10, further comprising an HF signal injection device for checking a functioning of said HF detector.
